(19) United States
(12) Patent Application Publication
(10) Pub. No.: US 2013/0241482 A1
(43) Pub. Date: Sep. 19, 2013

(54) GROUND FAULT INTERRUPT AUTOMATIC TEST METHOD FOR ELECTRIC VEHICLE

(71) Applicant: Albert Flack, Lake Arrowhead, CA (US)

(72) Inventor: Albert Flack, Lake Arrowhead, CA (US)

(21) Appl. No.: 13/769,158

(22) Filed: Feb. 15, 2013

Related U.S. Application Data
(63) Continuation of application No. PCT/US2011/048298, filed on Aug. 18, 2011.
Application No. PCT/US2011/048298 is a continuation-in-part of application No. PCT/US2011/032576, filed on Apr. 14, 2011.
Application No. PCT/US2011/032576 is a continuation-in-part of application No. 13/651,471, filed on Oct. 15, 2012.
Application No. 13/651,471 is a continuation of application No. PCT/US2011/032576, filed on Apr. 14, 2011.
(60) Provisional application No. 61/374,612, filed on Aug. 18, 2010.
(60) Provisional application No. 61/324,296, filed on Apr. 14, 2010.
(60) Provisional application No. 61/374,612, filed on Aug. 18, 2010.
(60) Provisional application No. 61/324,293, filed on Apr. 14, 2010.
(60) Provisional application No. 61/324,296, filed on Apr. 14, 2010.
(60) Provisional application No. 61/374,612, filed on Aug. 18, 2010.
(60) Provisional application No. 61/324,293, filed on Apr. 14, 2010.

(51) Int. Cl. G01R 31/28; H02J 7/00

(52) U.S. Cl. CPC G01R 31/2827; H02J 7/0029
USPC 320/109; 324/537

(57) ABSTRACT

In one implementation, the method for processor based automated testing of ground fault interrupt circuit for electric vehicle supply equipment is provided. In one implementation the method includes providing a simulated ground fault signal to a ground fault interrupt circuit and detecting at a processor that the ground fault interrupt circuit sensed the simulated ground fault signal. The method further includes commanding from the processor a utility power contactor to close while the ground fault interrupt circuit is disabling closing of the contactor and verifying the utility power contactor is not closed in response to commanding the utility power contactor to close.

### CROSS REFERENCE TO RELATED APPLICATIONS

This application is a continuation of PCT/US2011/048298 by Flack, entitled GROUND FAULT INTERRUPT AUTOMATIC TEST METHOD FOR ELECTRIC VEHICLE, filed on 18 Aug. 2011, herein incorporated by reference in its entirety.

PCT/US2011/048298 claims the benefit of U.S. Provisional Application 61/374,612, entitled GROUND FAULT INTERRUPT AUTOMATIC TEST METHOD FOR ELECTRIC VEHICLE, by Albert Flack, filed 18 Aug. 2010, hereby incorporated by reference in its entirety, and

PCT/US2011/048298 is continuation of PCT Application PCT/US2011/032576, entitled GROUND FAULT INTERRUPT CIRCUIT FOR ELECTRIC VEHICLE, by Albert Flack, international filing date 14 Apr. 2011, which claims the benefit of U.S. Provisional Application Ser. No. 61/324,296, entitled GROUND FAULT INTERRUPT CIRCUIT FOR ELECTRIC VEHICLE, by Albert Flack, filed Apr. 14, 2010, and claims benefit of 61/374,612, entitled GROUND FAULT INTERRUPT AUTOMATIC TEST METHOD FOR ELECTRIC VEHICLE, by Albert Flack, filed 18 Aug. 2010, and claims benefit of 61/324,293, entitled PILOT SIGNAL GENERATION CIRCUIT by Albert Flack, filed Apr. 14, 2010, all herein incorporated by reference in their entireties.

The present application is a continuation-in-part of U.S. application Ser. No. 13/651,417, entitled GROUND FAULT INTERRUPT CIRCUIT FOR ELECTRIC VEHICLE, by Flack et al., filed 14 Oct. 2012, which is a continuation of PCT Application PCT/US2011/032576, entitled GROUND FAULT INTERRUPT CIRCUIT FOR ELECTRIC VEHICLE, by Albert Flack, international filing date 14 Apr. 2011, which claims the benefit of U.S. Provisional Application Ser. No. 61/324,296, entitled GROUND FAULT INTERRUPT CIRCUIT FOR ELECTRIC VEHICLE, by Albert Flack, filed Apr. 14, 2010, and claims benefit of 61/374,612, entitled GROUND FAULT INTERRUPT AUTOMATIC TEST METHOD FOR ELECTRIC VEHICLE, by Albert Flack, filed 18 Aug. 2010, and claims benefit of 61/324,293, entitled PILOT SIGNAL GENERATION CIRCUIT by Albert Flack, filed Apr. 14, 2010, all herein incorporated by reference in their entireties.

### BACKGROUND

One way to charge an electric vehicle is to supply the vehicle with power so that a charger in the vehicle can charge the battery in the vehicle. If there is a ground fault in the electrical system in the car when electrical power is supplied, and someone touches car while grounded, that person could be shocked. A ground fault interrupt is typically provided to prevent this. If the ground fault interrupt is not functioning properly, however, risk of shock could still be present.

Thus, what is needed is a ground fault interrupt test to ensure the ground fault interrupt functions properly. Moreover, what is needed is an automated test.

### SUMMARY

In one implementation, a method for processor based automated testing of ground fault interrupt circuit for electric vehicle supply equipment is provided. In one implementation the method includes providing a simulated ground fault signal to a ground fault interrupt circuit and detecting at a processor that the ground fault interrupt circuit sensed the simulated ground fault signal. The method further includes commanding from the processor a utility power contactor to close while the ground fault interrupt circuit is disabling closing of the contactor and verifying the utility power contactor is not closed in response to commanding the utility power contactor to close.

In some implementations the commanding of the utility power contactor to close may include commanding the utility power contactor to close in response to the processor detecting that the ground fault interrupt circuit sensed the simulated ground fault signal.

In some implementations the method may further include receiving a request for charging via a pilot signal and commanding the utility power contactor to close in response to the request for charging on the pilot signal prior to resetting the ground fault interrupt circuit.

In some implementations the method may further include resetting the ground fault interrupt circuit while commanding the utility power contactor to close and verifying with the processor that the contactor closes after the resetting of the ground fault interrupt circuit while the processor is commanding the utility power contactor to close.

In some implementations the method may further include oscillating a pilot signal, receiving a request for charging via the oscillating pilot signal, and commanding the utility power contactor to close in response to the request for charging on the pilot signal while the ground fault interrupt circuit disables closing of the contactor.

### BRIEF DESCRIPTION OF THE DRAWINGS

The features and advantages of the present invention will be better understood with regard to the following description, appended claims, and accompanying drawings where:

FIG. 1 shows a schematic view of a cable to connect utility power to an electric vehicle (not shown) along with some associated circuitry.

FIG. 2 shows an enlarged view schematic drawing of the GFI circuit of FIG. 1.

FIG. 3 shows a schematic view of a contactor control circuit.

FIG. 4 shows an enlarged more complete schematic of the pilot circuitry shown in partial schematic in FIG. 1.

FIG. 5 is a partial schematic showing a microprocessor, which may be used to govern the output of the GFI circuit.

FIG. 6 shows a simplified plot of an example of possible charge accumulation by the double stage filter leading to a fault detection by the comparator.

FIG. 7 is a simplified schematic diagram of a pilot signal generation circuit in accordance with one possible embodiment.

FIG. 8 is an example timing diagram of signals for the pilot circuit of FIG. 7.

FIGS. 9 and 10 are simplified timing diagrams illustrating implementations for automatic GFI testing with no fault (FIG. 9) and with a fault (FIG. 10).

### DESCRIPTION

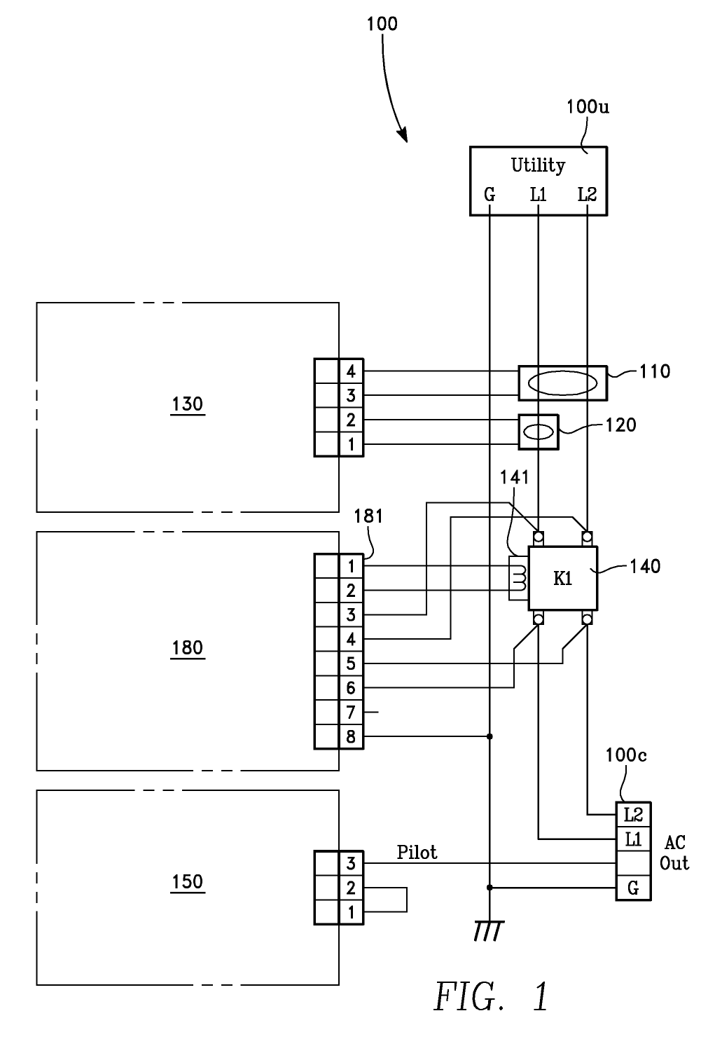

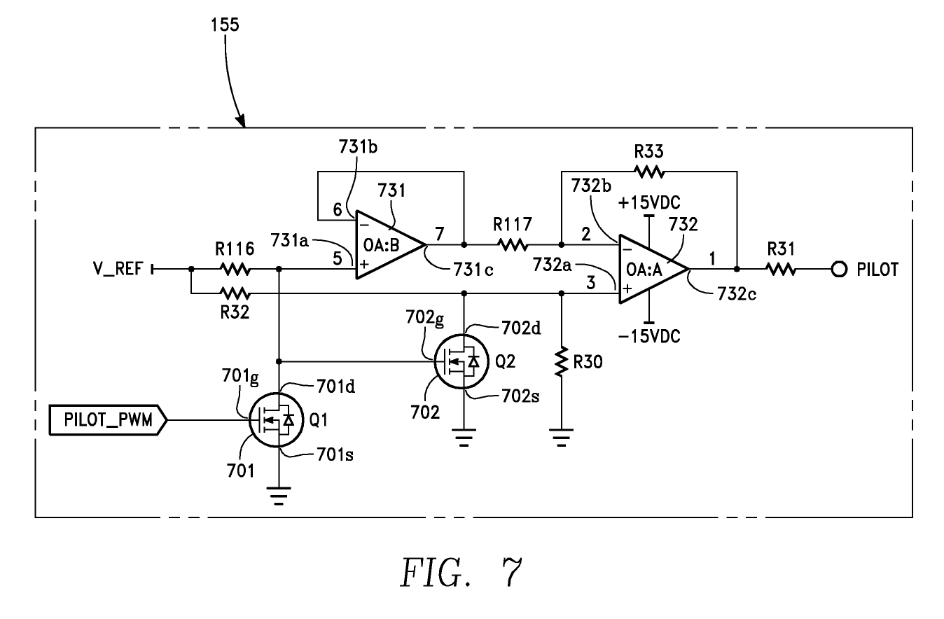

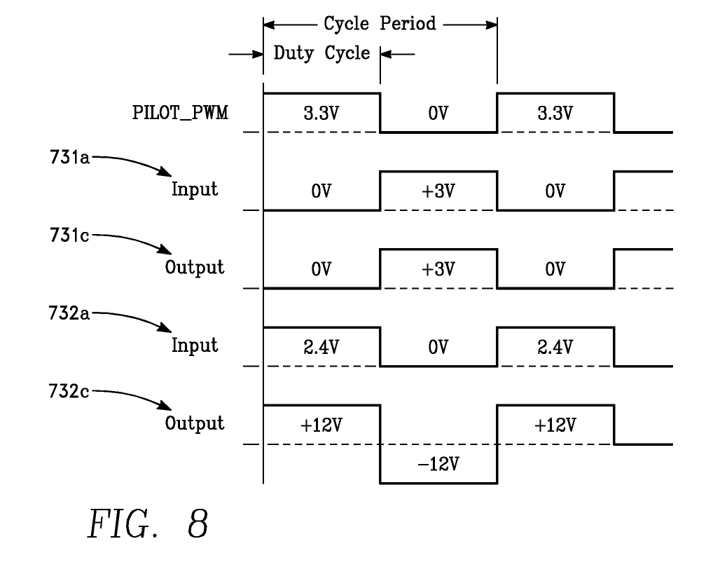

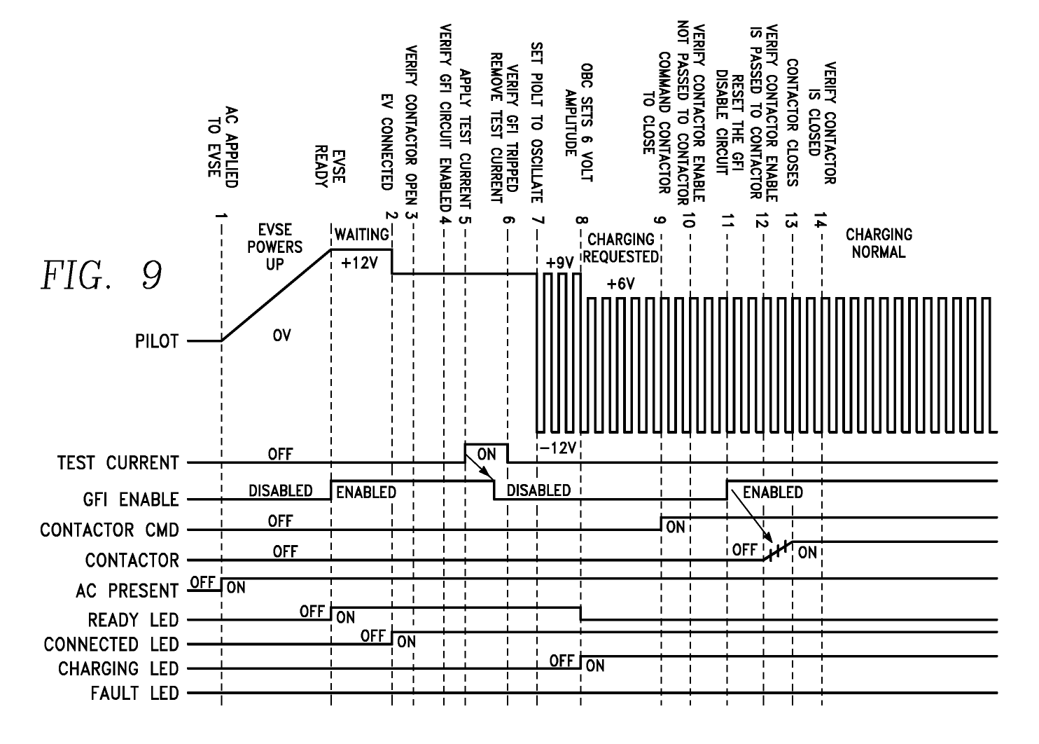

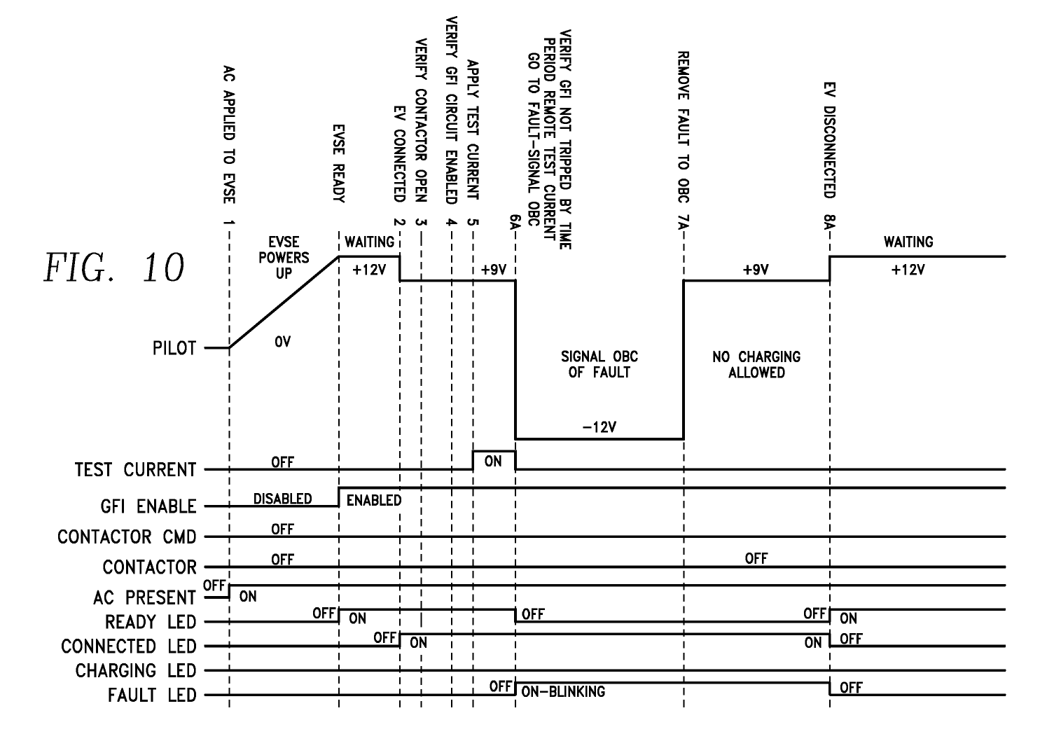

The below discussion with reference to FIGS. 1-6 illustrate a possible ground fault interrupt circuit and associated circuitry for use with the methods of FIGS. 7 and 8. FIGS. 9 and 10 provide implementations of ground fault interrupt automatic testing.

FIGS. 1-8

The below discussion with reference to FIGS. 1-6 illustrate a possible ground fault interrupt circuit and associated circuitry for use with the methods of FIGS. 7 and 8.

FIG. 1 shows a schematic view of a cable 100 to connect utility power to an electric vehicle (not shown) along with some associated circuitry. In the embodiment of FIG. 1, the cable 100 contains L1 and L2 and ground G lines. The cable 100 connects to utility power at one end 100u and to an electric vehicle (not shown) at the other end 100c. The electric vehicle (not shown) could have an onboard charger, or, the electric vehicle end 100c of the cable 100 could be connected to a separate, optionally free standing, charger (not shown). The separate charger (not shown) would in turn be connected to the electric vehicle for charging onboard batteries, or other charge storage devices. In other embodiments not shown, a charger could be integrated into the cable 100, if desired.

GFI Circuit

FIGS. 1-6

The cable 100 contains current transformers 110 and 120. The current transformer 110 is connected to a ground fault interrupt or GFI circuit 130 which is configured to detect a differential current in the lines L1 and L2 and indicate when a ground fault is detected. Contactor 140 may be open circuited in response to a detected ground fault to interrupt utility power from flowing on lines L1 and L2 to the vehicle (not shown).

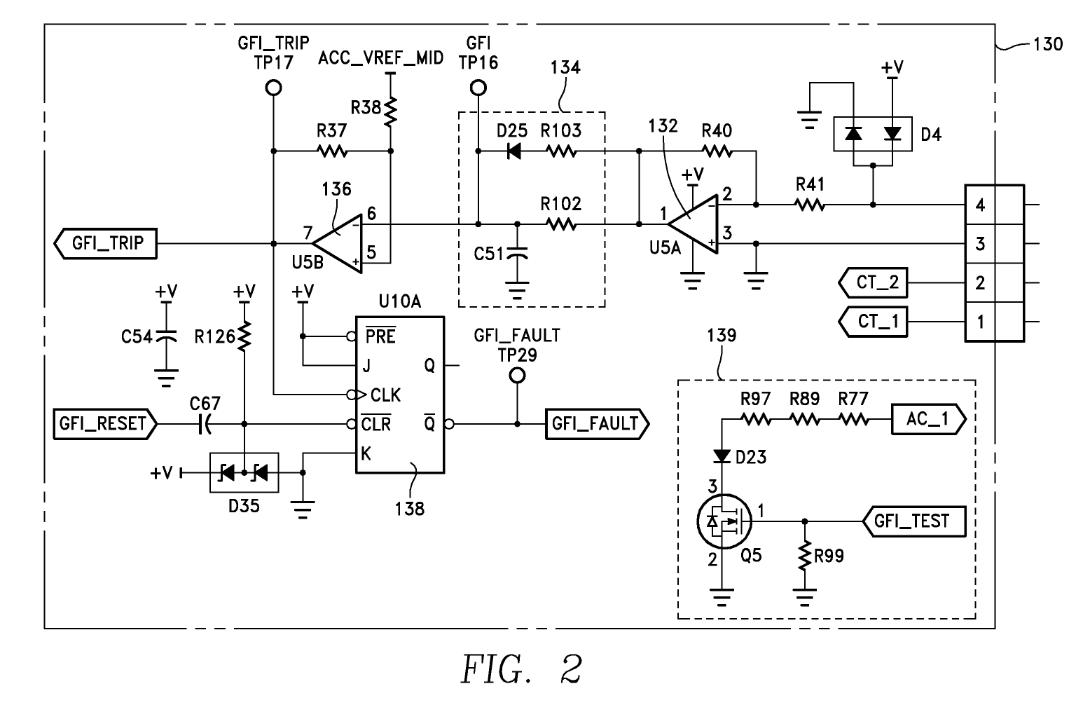

FIG. 2 shows an enlarged view schematic drawing of the GFI circuit 130 of FIG. 1. In the embodiment of FIG. 2, the GFI circuit 130 is designed to trip in the 5-20 mA range for GFI in accordance with the UL 2231 standard.

A signal provided by current transformer 110 (FIG. 1) at pins 3 and 4 of the GFI circuit 130 is amplified by op amp 132 to a voltage reference. That voltage reference is filtered by a double stage RC filter 134 to eliminate spurious noise spikes.

Fault current detected by current transformer 110 (FIG. 1) is converted to voltage by gain amplifier 134 for comparison by comparator 136. The output of the gain amplifier 132 is filtered prior to being supplied to the comparator 136 with the double stage RC filter 134 to remove spurious noise that could cause nuisance shut downs. Output of comparator 136 is latched with flip-flop 138 so that contactor 140 (FIG. 1) does not close after a fault has been detected. The comparator 136 provides a GFI_TRIP signal output, which is an input to the fault latch 138 to produce a latched GFI_FAULT signal.

The double stage filter 134 provides a delay so that the shut-off circuit does not immediately shut off if a fault is detected. The double stage filter 134 is a half-wave rectified circuit that allows an incoming pulse width that is less than 50% in some embodiments, or even as small as about 38% in some embodiments, to accumulate over time so that it will charge at a faster rate than it discharges. The double stage filter 134 accumulates charge and acts an energy integrator. Thus, the GFI circuit 130 waits a time period before causing shut down. This is because it is not desirable to have an instantaneous shut down that can be triggered by noise in the lines L1 or L2, or in the GFI circuit 130. The GFI circuit 130 should trip only if a spike has some predetermined duration. In the embodiment shown, that duration is one to two cycles.

The filter 134 charges through R102 and R103. When it discharges, it only discharges through R102, so it charges more current than it discharges over time. The double stage filter 134 is a half wave rectified circuit due to diode D25.

Diodes D4 provide surge suppression protection. In typical embodiments, the gain amplifier 132 may actually have surge suppression protection. Despite this, diodes D4 are added to provide external redundant protection to avoid any damage to the gain amplifier 132. This redundant protection is significant, because if the 132 gain amplifier is damaged, the GFI protection circuit 130 may not function, resulting in inadequate GFI protection for the system. For example, without the redundant surge suppressing diodes D4, if a power surge were to damage the gain amplifier 132 so that it no longer provided output, the GFI circuit 130 would no longer be able to detect faults. Since UL 2231 allows utility power L1 and L2 power to be reconnected after a GFI circuit detects a ground fault surge, utility power L1 and L2 could conceivably be reconnected after the gain amplifier 132 had been damaged. It is significant to note that the diodes D4 are connected to the upper and lower reference voltage busses of the circuit, i.e. ground and 3 volts, respectively, so that they can easily dissipate surge current without causing damage to the circuitry. Thus, the redundant surge suppression diodes D4 provide an additional safety feature for the GFI protection circuit 130.

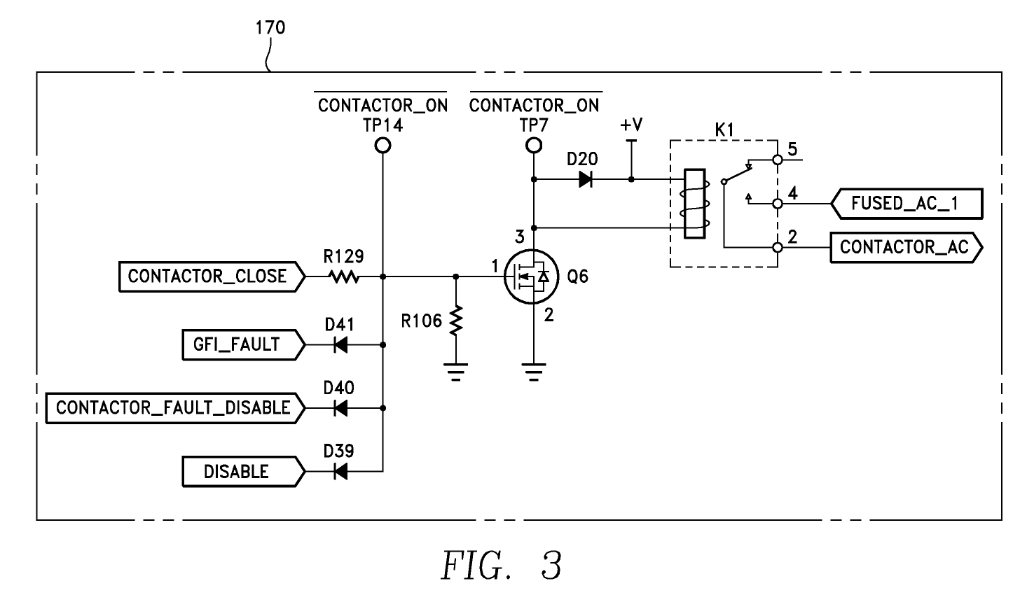

FIG. 3 shows a schematic view of a contactor control circuit 170. The contactor control circuit 170 opens/closes the contactor 140 (FIG. 1) to disconnect/connect the utility power L1 and L2 from/to the vehicle connector 100c. As discussed above with reference to FIG. 2, the GFI_TRIP signal is output by the comparator 136 and is an input to the fault latch 138 to produce the GFI_FAULT signal. The GFI_FAULT signal output by the fault latch 138 is an input to the contactor control circuitry 170, shown in FIG. 3, used to control the contactor control relay K1. The contactor control relay K1 is used to open/close the contactor 140 (FIG. 1) to disconnect/connect the utility power L1 and L2 from/to the vehicle connector 100c. The CONTACTOR_AC signal output by the contactor control relay K1 is connected to the contactor coil 141 (FIG. 1) through pin 1 of the connector 181 (FIG. 1) associated with the utility present circuitry 180 (FIG. 1).

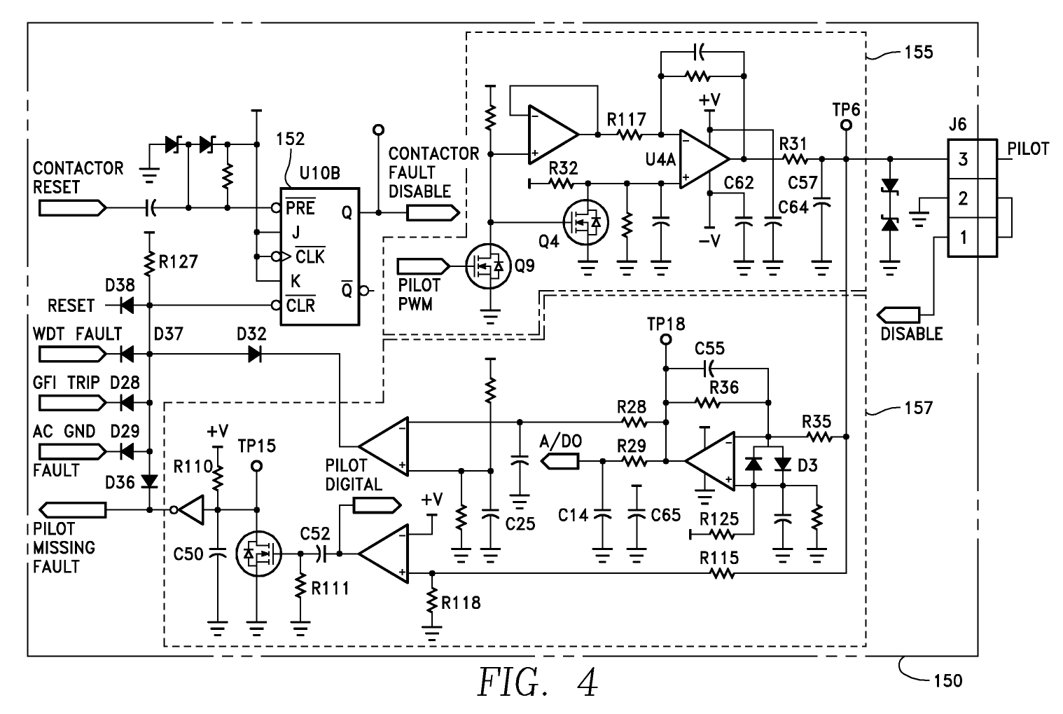

The GFI_TRIP signal output by the comparator 136 (FIG. 2) is not only provided to the contactor control circuit 170 (FIG. 3), but also is provided as an input to the contactor disable latch 152, shown in FIG. 4 to produce a CONTACTOR_FAULT_DISABLE signal. FIG. 4 shows an enlarged more complete schematic view of the pilot circuitry 150 shown in partial schematic in FIG. 1. Additionally, the contactor disable latch 152 (FIG. 4) is an input to the contactor control circuitry 170 (FIG. 3) to control the contactor control relay K1 (FIG. 3). The CONTACTOR_FAULT_DISABLE signal is used to open the contactor control relay K1 (FIG. 3), which opens the contactor 140 (FIG. 1) to open/close circuit the utility power L1 and L2. This provides a redundant circuit for this important safety control circuit. Further, it requires the reset of both latches 138 (FIGS. 2) and 152 (FIG. 4) to reconnect L1 and L2 utility power to the vehicle connector 100c. This provides further software redundancy for this important safety control circuit.

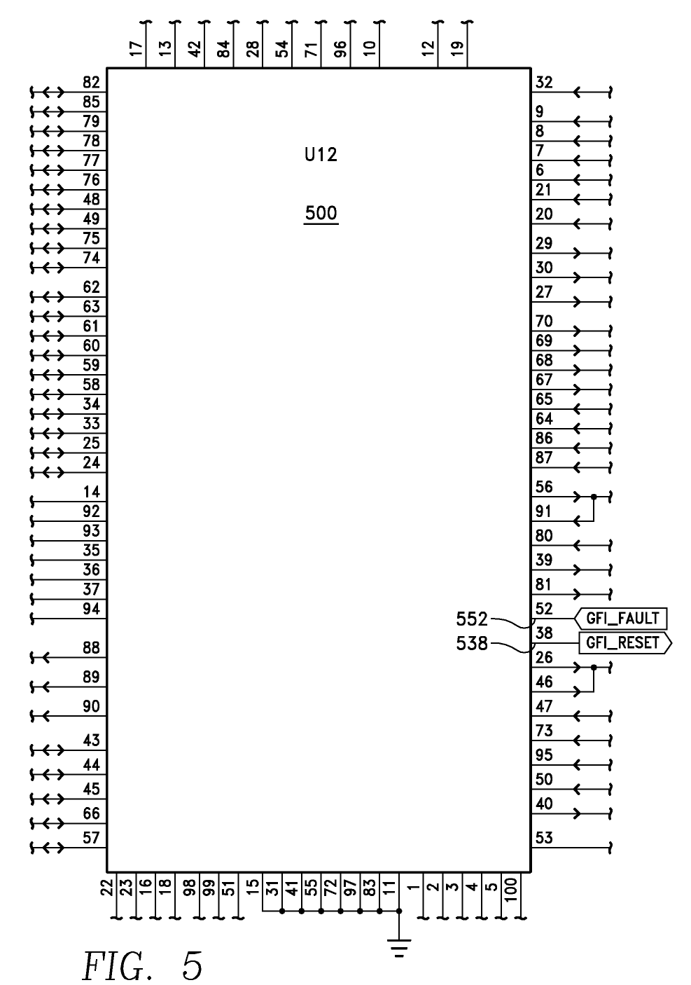

FIG. 5 is a partial schematic showing a microprocessor 500, which may be used to govern the output of the GFI circuit 130 (FIG. 2). Referring to FIGS. 2 and 5, the GFI_FAULT output signal from the fault latch 138 is provided as an input at pin 552 to the microprocessor 500. The microprocessor 500 outputs at pin 538 the GFI_RESET signal to the GFI circuit 130 to control the reset of the GFI circuit 130, in accordance with a predetermined standard, such as UL 2231. This may be accomplished by outputting the GFI_RESET signal to the fault latch 138, and to the CONTACTOR_RESET to the contactor disable latch 152 (FIG. 4).

Also, the microprocessor 500 may also output at pin 81 the GFI_TEST signal, which causes a GFI test circuit 139 to simulate a ground fault for testing the functionality of the contactor 140 (FIG. 1). The GFI test circuit 139 output AC_1 provides a path via pin 2 of the connector 181 to the contactor coil 141 (FIG. 1) to exercise the contactor 140.

Additionally, the microprocessor 500 provides a CONTACTOR_CLOSE signal output to the contactor close circuit to close the contactor control relay K1 (FIG. 3).

Further, the microprocessor 500 may provide signals to the pilot circuit, such as the PILOT_PWM discussed below with reference to FIGS. 7 and 8.

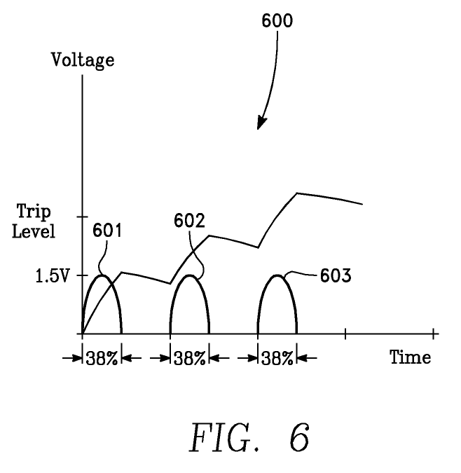

FIG. 6 shows a simplified plot 600 of an example of possible charge accumulation by the double stage filter 134 (FIG. 2) leading to a fault detection by the comparator 136 (FIG. 2). Referring to FIGS. 2 and 6, since the double stage filter 134 discharges slower than it charges, several successive current pulse detections 601, 602, and 603 would be required to cause sufficient charge to accumulate a voltage level that would cause the comparator to indicate a GFI TRIP. Thus, faults by spurious noise can be minimized.

In this simplified example plot, a 1.5 volts pulse of about 38% of the duty cycle for three successive cycles causes sufficient charge to accumulate a GFI TRIP signal. Other embodiments are possible by appropriate selection of the R102, R103, and C51.

Pilot Signal Circuit

FIGS. 1, 4, 5, and 7-8

In some embodiments a PILOT signal in accordance with the SAE J-1772 standard is provided. The SAE-J1772 standard, incorporated herein by reference in its entirety, requires precise voltage levels on the PILOT signal, which communicates a charge current command from the electric vehicle supply equipment system, illustrated in FIGS. 1-5, to the electric vehicle. A certain level of error is allowed but more precise signal sourcing provides a more confident operational profile. In various embodiments, the pilot signal generation circuit 150 generates a clean and precise PILOT signal. The pilot signal generation circuit 150 provides the PILOT signal via the connector 100c at the vehicle end of the cable 100. The pilot signal communicates information between the battery charger (not shown) in the vehicle and the electric power supply control system illustrated in FIGS. 1-5.

FIG. 7 is a simplified schematic diagram of a pilot signal generation circuit 155 in accordance with one possible embodiment. FIG. 8 is an example timing diagram of signals for the pilot circuit 155 of FIG. 7. In the embodiment of FIG. 7, the PILOT signal is to be sourced at a value of from +12.0 Volts to −12.0 Volts in a pulse width modulated (PWM) square wave with a frequency of 1,000 Hz. A logic level pulse width modulated square wave PILOT_PWM signal controls the duty cycle and frequency. In the embodiment of FIG. 7 and the timing diagram illustrated in FIG. 8, the PILOT_PWM signal is a logic level signal of 0-3.3 Volts. The logic level signal PILOT_PWM may be any other voltage(s) depending on the embodiment. An absolute reference voltage V_REF provides the precision voltage value for the circuit 155. In this example V_REF is +3.0V. Operational amplifiers 731 and 732, and resistors R30-R32 and R116-R117 are used in conjunction with two Field Effect Transistors or FETs 701 and 702 to generate the final PILOT signal. In this example, the typical resistance values for R30-R32, R116, and R117 are given in ohms as 100K, 1.00K, 25.0K, 10.0K, and 25.0K, respectively, but the values can be altered to change the circuit 155 performance. In other embodiments, the transistors 701 and 702 may be another type, such as bipolar for example.

As shown in FIG. 7, the pilot signal generation circuit 155 has a first operational amplifier 731 having a non-inverting input connected via a first resistor R116 to receive a source reference voltage V_REF. The output 731c is directly connected to the inverting input 731b of the first operational amplifier. A second operational amplifier 732 has its non-inverting input 732a connected via a second resistor R32 to receive the source reference voltage V_REF. The non-inverting input 732a is also connected in parallel to ground or other reference voltage via resistor R30. The inverting input 732b is connected via a resistor R117 to the output 731c of the first operational amplifier. The output 732c connected via a resistor R33 to the non-inverting input 732b of the second operational amplifier 732.

Furthermore, the pilot signal generation circuit 155 has a first transistor 701 with its gate 701g connected to receive a logic level pulse width modulated control signal PILOT_PWM. The logic level pulse width modulated control signal PILOT_PWM may be supplied by the microprocessor 500 (FIG. 5). The drain 701d is connected to the non-inverting input 731a of the first operational amplifier 731, and the source 701s is connected to ground or other reference voltage. A second transistor 702 has a gate 702g connected to the drain 701d of the first transistor 701. The drain 702d of the second transistor 702 is connected to the non-inverting input 732a of the second operational amplifier 732, and the source 702s is connected to ground or other reference voltage.

Referring again to FIGS. 7 and 8, the PILOT_PWM signal may be a digital signal created by an external control source, such as a microprocessor 500 (FIG. 5). The logic level signal PILOT_PWM controls operation of the pilot signal generation circuit 155.

When the PILOT_PWM signal is low at the gate 701g of transistor 701, transistor 701 is open from drain 701d to source 701s. The voltage on transistor drain 701d then feeds into transistor gate 702g causing it to turn on, shorting its drain 702d to source 702s. In this condition, the input 731a of the first operational amplifier 731 has a high impedance +3.00 Volts applied to it, which is then buffered by the second operational amplifier 732 to provide a low impedance signal at +3.00 Volts for the second operational amplifier 732 to use as a signal source. Input 732a of the second operational amplifier 732 is held at 0 Volts by transistor 702. As a result, the output of 732c of the second operational amplifier 732 then has a negative voltage proportional to the gain of the second operational amplifier 732 circuit, specified by the ratio of R33 to R117; in this case, −12.00 Volts.

When the PILOT_PWM signal is high, 701 is shorted from drain 701d to source 701s. The 0 Volts on drain 701d of transistor 701 then feeds into gate 702g of transistor 702 causing it to be open from drain 702d to source 702s. In this condition, input 731a the first operational amplifier 731 has 0 Volts applied to it, which is then buffered by the first operational amplifier 731 to provide 0 Volts for the second operational amplifier 732 to use as a signal source at input 732b. Input 732a of the second operational amplifier 732 is fed by the +3.00 Volts reference V_REF and differentially amplified against the 0 Volts signal provided from output 731c. As a result, the output 732c of the second operational amplifier 732 has a positive voltage proportional to the gain of the second operational amplifier 732 circuit, specified by R33, R117, R30 and R32; in this case, +12.00 Volts.

Thus, by use of this circuit 155, a high or low logic level signal PILOT_PWM of imprecise voltage will provide a precise +12 Volt to −12 Volt square wave output suitable for use as the control communication signal source PILOT for the SAE-J1772 standard signal generation. Accuracy is only limited by component selection. Because this circuit 155 is absolute reference and amplifier regulated, the +/−12 volt signals are extremely accurate with no undesired component losses. This supports and enhances the application of the SAE J-1772 standard for reading the communication level control voltages without errors.

If the onboard charger sees a signal amplitude too low or too high, or improper frequency or pulse width within an expected range, it will shut off because it will assume that the integrity of the connection is bad. So it is important to have a precise PILOT signal.

In various embodiments of the pilot signal generation circuit 155, the operational amplifier 731 is configured to buffer the input 731a to the output 731c. The operational amplifier 732 is configured with resistors R30, R32, R33, and R117 as a differential amplifier. The transistor 701 is connected to the operational amplifier 731 to shunt the source reference voltage V_REF at the input 731a of the operational amplifier 731. The transistor 702 is connected to the operational amplifier 732 to shunt the source reference voltage V_REF at the input 732a of the operational amplifier 732 in response to a voltage level at the input 731a of the operation amplifier 731.

Thus, the pilot signal generation circuit 155 is configured to receive a logic level pulse width modulated signal PILOT_PWM at the input 701g of the transistor 701 and to provide a pulse width modulated bipolar signal PILOT at precision voltage levels at the output 732C of the second operational amplifier 732.

In various embodiments, the pilot generation circuit 155 is able to provide an output PILOT signal with precise voltage levels to within about 1% at +/−12 Volts.

The voltage of the PILOT signal will indicate the status of the connection between the cable 100 and the vehicle (not shown). In this example, a PILOT signal of +12 Volts indicates that the connector 100c is disconnected from the vehicle and not stowed. Optionally, a PILOT signal voltage of +11 Volts may be used to indicate that the connector 110c is stowed, at a charging station, for example. A PILOT signal voltage of +9 Volts indicates that the vehicle is connected. A PILOT signal voltage of +6 Volts indicates that the vehicle is charging without ventilation. A PILOT signal voltage of +3 Volts indicates that the vehicle is charging with ventilation. A PILOT signal voltage of 0 Volts indicates that there is a short or other fault. A PILOT signal voltage of −12 Volts indicates that there is an error onboard the vehicle.

A pilot detection circuit 157 within the pilot circuit 150 detects the voltages, generates, and provides a PILOT_DIGITAL signal to the microprocessor 500 (FIG. 5). The pilot detection circuit 157 also generates and provides a PILOT_MISSING_FAULT signal to the microprocessor 500 (FIG. 5). In response, the microprocessor 500 controls the connection of the utility power L1 and L2. For example, the microprocessor 500 can set the CONTACTOR CLOSE signal, discussed above, to cause the control contactor 170 to open the contactor 140 if a PILOT_MISSING_FAULT is detected.

Ground Fault Auto Test

FIGS. 9 and 10

In order to provide the capability of auto-restart, there should also be an automatic GFI test. The automatic GFI test function can best be performed at the beginning of each START or RESTART charge cycle. If the test is passed then the charge cycle can proceed. If the GFI test fails then the charge cycle is disallowed.

Normally the GFI test checks the entire sense and control circuits, including the ability of the contactor 140 (FIG. 1) ability to open. This would normally require that the GFI test first close the contactor 140 (FIG. 1) and then test the GFI circuit 130(FIG. 1), which should result in the contactor 140 (FIG. 1) opening. This process would subject the On Board Charger (OBC)(not shown) of the electric vehicle (not shown) to the application and removal of AC power. Also, the application of power could overshadow the test if an additional external current leakage was induced during the application of AC power to the OBC.

FIGS. 9 and 10 are simplified timing diagrams illustrating implementations for automatic GFI testing with no fault (FIG. 9) and with a fault (FIG. 10) Note that steps 1 thru 5 on the FIGS. 9 and 10 are identical. From step 6 on, the methods are different.

On one implementation of the new approach to the GFI test is to apply AC power to the electric vehicle service equipment (EVSE) or charger at step 1 and then connect the charger plug to the electric vehicle (EV) at step 2. Once the EVSE senses the connected status (9V Pilot level), it first verifies that the contactor is not closed at step 3, which may be by performing a contactor health check. This of course would have been the natural state at this point. It also verifies that the GFI_TRIP signal (FIG. 2) is not in the disabled state at step 4. The GFI test is then applied at step 5, presenting a false GFI current signal to the sense circuit. This small current trips the GFI control circuit at step 6 which is then sensed by the CPU or other processor 500 (FIG. 5). If this succeeds then the basic sense and disable portion of the system is verified to be functional. The next step of the process is to try to close the breaker by CPU 500 (FIG. 5) control, which will prove that the contactor 140 (FIG. 1) is or is not able to be closed. Since this aspect of the test overlaps the subsequent charge cycle function of closing the contactor 140 (FIG. 1), they may be combined as a smooth single process.

The EVSE continues to complete the test and provide power to the EV as follows. The Pilot signal begins oscillating at step 7 and the OBC then sets the amplitude to 6 (or 3) volts at step 8. The CPU commands the contactor to close at step 9 and monitors the next stage of the GFI ENABLE signal at 10 which is still active (in the disabled state). If the next stage is seen to not be able to close the contactor then the final control element of the GFI has been verified. The GFI circuit is reset at step 11 and the contactor driver signal is seen to go high at step 12 verifying that the contactor will close. The contactor subsequently closes at step 13 and is verified at step 14, such as by performing a contactor health check. Normal charging then proceeds.

It is significant to note that the final circuit verification will take about five microseconds and as such will not have time to actually close the contactor relay (which takes five milliseconds) and therefore not be able to close the contactor (ten milliseconds), so no power will ever leave the EVSE during this test if it fails.

Referring to FIG. 10, if the signal is seen after step 5 to enable the contactor then the GFI test is determined to have failed. The CPU will stop the test process and go to the fault state at 6A where the OBC is informed about the fault by setting the Pilot to −12V. After the fault is indicated to the OBC as an EVSE fault, the Pilot signal is returned to the high state at 7A. At some time later the charge plug is disconnected from the EV, resetting the fault at 8A.

A manual version of this test can be implemented at any time with or without an EV.

In one implementation of the manual GFI test while charging, when the EV is in a charging condition, is to push the control buttons for the manual test start. The contactor is already closed so the EVSE turns on the GFI test circuit which applies the trigger current to the utility line. The GFI sense circuit will trip within 30 mSec which will force open the contactor. The test fails if the contactor is not sensed to open by reading the control line feedback signal, the CONTACTOR_ON signal (at a test point if desired).

In one implementation of the manual GFI test while not connected to an EV, is to push the control buttons for the manual test start. The sequence will follow a similar pattern as with the auto restart sequence but the voltage on the pilot will remain at +12Vdc and not go to +9VDC. This will insure by hardware that the contactor will not close. The trip current is actuated and the GFI trip function can be then traced by reading the GFI_FAULT signal (at a test point if desired). This is a partial verification of the total circuit. The contactor close function can be implemented by taking the Pilot signal to −12VDC through DSP control. This will allow contactor closure but that could be dangerous since it may happen when the charge plug is out in the open.

It is worthy to note that any reference to “one embodiment” or “an embodiment” means that a particular feature, structure, or characteristic described in connection with the embodiment may be included in an embodiment, if desired. The appearances of the phrase “in one embodiment” in various places in the specification are not necessarily all referring to the same embodiment.

The illustrations and examples provided herein are for explanatory purposes and are not intended to limit the scope of the appended claims. This disclosure is to be considered an exemplification of the principles of the invention and is not intended to limit the spirit and scope of the invention and/or claims of the embodiment illustrated.

Those skilled in the art will make modifications to the invention for particular applications of the invention.

The discussion included in this patent is intended to serve as a basic description. The reader should be aware that the specific discussion may not explicitly describe all embodiments possible and alternatives are implicit. Also, this discussion may not fully explain the generic nature of the invention and may not explicitly show how each feature or element can actually be representative or equivalent elements. Again, these are implicitly included in this disclosure. Where the invention is described in device-oriented terminology, each element of the device implicitly performs a function. It should also be understood that a variety of changes may be made without departing from the essence of the invention. Such changes are also implicitly included in the description. These changes still fall within the scope of this invention.

Further, each of the various elements of the invention and claims may also be achieved in a variety of manners. This disclosure should be understood to encompass each such variation, be it a variation of any apparatus embodiment, a method embodiment, or even merely a variation of any element of these. Particularly, it should be understood that as the disclosure relates to elements of the invention, the words for each element may be expressed by equivalent apparatus terms even if only the function or result is the same. Such equivalent, broader, or even more generic terms should be considered to be encompassed in the description of each element or action. Such terms can be substituted where desired to make explicit the implicitly broad coverage to which this invention is entitled. It should be understood that all actions may be expressed as a means for taking that action or as an element which causes that action. Similarly, each physical element disclosed should be understood to encompass a disclosure of the action which that physical element facilitates. Such changes and alternative terms are to be understood to be explicitly included in the description.

Having described this invention in connection with a number of embodiments, modification will now certainly suggest itself to those skilled in the art. The example embodiments herein are not intended to be limiting, various configurations and combinations of features are possible. As such, the invention is not limited to the disclosed embodiments, except as required by the appended claims.

What is claimed is:

1. A method for processor based automated testing of a ground fault interrupt circuit in electric vehicle supply equipment, the method comprising:
a) detecting whether a utility power contactor is open after connecting the electric vehicle supply equipment to an electric vehicle;
b) verifying the ground fault interrupt circuit is enabled so as to allow closing of the contactor;
c) applying a test signal to simulate a ground fault;
d) verifying that the ground fault interrupt circuit tripped to disable closing of the contactor in response to the test signal;
e) commanding the contactor to close from a processor while the ground fault interrupt circuit is tripped;
f) verifying the contactor does not close in response to commands from the processor while the ground fault interrupt circuit is tripped;
g) resetting the ground fault interrupt circuit; and
h) verifying the contactor closes after resetting the ground fault interrupt circuit.

2. The method of claim 1, wherein verifying the contactor does not close in response to commands from the processor while the ground fault interrupt circuit is tripped comprises:
a) commanding the contactor to close the after the processor detects that the ground fault interrupt circuit is tripped; and
b) commanding the contactor to close in response to a request for charging on a pilot signal while the ground fault interrupt circuit is tripped.

3. The method of claim 1, wherein resetting the ground fault interrupt circuit comprises resetting the ground fault interrupt circuit after initiating and during the commanding of the contactor to close with the processor.

4. The method of claim 1 further comprising verifying that the contactor is not closed and that the ground fault interrupt circuit is not tripped prior to providing a simulated ground fault signal to a ground fault circuit.

5. A method for processor based automated testing of ground fault interrupt circuit for electric vehicle supply equipment, the method comprising:
a) providing a simulated ground fault signal to a ground fault interrupt circuit;
b) detecting at a processor that the ground fault interrupt circuit sensed the simulated ground fault signal;
c) commanding from the processor a utility power contactor to close while the ground fault interrupt circuit is disabling closing of the contactor; and
d) verifying the utility power contactor is not closed in response to commanding the utility power contactor to close.

6. The method of claim 5, wherein commanding comprises commanding the utility power contactor to close in response to the processor detecting that the ground fault interrupt circuit sensed the simulated ground fault signal.

7. The method of claim 6 further comprising:
a) receiving a request for charging via a pilot signal; and
b) commanding the utility power contactor to close in response to the request for charging on the pilot signal prior to resetting the ground fault interrupt circuit.

8. The method of claim 7 further comprising:
a) resetting the ground fault interrupt circuit while commanding the utility power contactor to close; and
b) verifying with the processor that the contactor closes after the resetting of the ground fault interrupt circuit while the processor is commanding the utility power contactor to close.

9. The method of claim 5 further comprising:
a) oscillating a pilot signal;
b) receiving a request for charging via the oscillating pilot signal; and
c) commanding the utility power contactor to close in response to the request for charging on the pilot signal while the ground fault interrupt circuit disables closing of the contactor.

10. The method of claim 5 further comprising generating a ground fault interrupt tripped signal at the ground fault interrupt circuit in response to the simulated ground fault signal and providing the ground fault interrupt tripped signal to the processor.

11. The method of claim 10, wherein commanding comprises commanding the utility power contactor to close with the processor after the ground fault interrupt tripped signal is received by the processor.

12. The method of claim 5, wherein detecting at the processor comprises verifying that the ground fault circuit sensed the simulated ground fault.

13. The method of claim 5, wherein commanding the utility power contactor to close occurs after the processor detects that the ground fault interrupt circuit sensed the simulated ground fault signal and prior to resetting the ground fault interrupt circuit.

14. The method of claim 5, further comprising verifying that the contactor is not closed and that a ground fault interrupt tripped signal is not in the disabled state prior to providing a simulated ground fault signal to a ground fault circuit.

15. A method for processor based automated testing of a ground fault interrupt circuit in electric vehicle supply equipment, the method comprising:
a) providing a simulated ground fault signal to a ground fault interrupt circuit;
b) detecting at a processor that the ground fault circuit sensed the simulated ground fault signal;
c) commanding from the processor a utility power contactor to close while the ground fault interrupt circuit disables closing of the contactor;
d) verifying the utility power contactor is not closed in response to the processor commanding the utility power contactor to close while the ground fault interrupt circuit disables closing of the contactor;
e) oscillating a pilot signal;
f) receiving a request for charging on the pilot signal;
g) commanding the utility power contactor to close in response to the request for charging on the pilot signal while the ground fault interrupt circuit is disabling closing of the contactor;
h) verifying the utility power contactor is not closed in response to the request for charging on the pilot signal while the ground fault interrupt circuit is disabling closing of the contactor;
i) resetting the ground fault interrupt circuit while the processor is commanding the utility power contactor to close; and
j) verifying with the processor that the contactor closes after the resetting of the ground fault interrupt circuit while the processor is commanding the utility power contactor to close.

16. An electric vehicle supply equipment for supplying electrical power from utility power to an electric vehicle, the electrical vehicle supply equipment comprising:
a) a power cable adapted to connect utility power to an electric vehicle via a contactor;
b) a ground fault interrupt circuit capable of detecting a ground fault and controlling the state of the contactor; and
c) a processor connected to the ground fault interrupt circuit and connected so as to control the state of the contactor, the processor being configured to perform the steps comprising:
(1) providing a simulated ground fault signal to the ground fault interrupt circuit;
(2) detecting that the ground fault interrupt circuit sensed the simulated ground fault signal;
(3) commanding the contactor to close while the ground fault interrupt circuit is disabling closing of the contactor; and
(4) verifying the contactor is not closed in response to commanding the contactor to close.

17. The electric vehicle supply equipment of claim 16, wherein the processor is configured to perform the step of commanding by commanding the contactor to close in response to the processor detecting that the ground fault interrupt circuit sensed the simulated ground fault signal.

18. The electric vehicle supply equipment of claim 16, further comprising a pilot circuit in communication with the processor, and wherein the processor is configured to perform the further steps comprising:
a) receiving a request for charging via the pilot circuit; and
b) commanding the contactor to close in response to the request for charging prior to resetting the ground fault interrupt circuit.

19. The electric vehicle supply equipment of claim 18, wherein the processor is configured to perform the further steps comprising:
a) resetting the ground fault interrupt circuit while commanding the contactor to close; and
b) verifying the contactor closes after the resetting of the ground fault interrupt circuit commanding the contactor to close.

20. The electric vehicle supply equipment of claim 16, wherein the ground fault interrupt circuit is configured to generate a ground fault interrupt tripped signal at in response to the simulated ground fault signal and provide the ground fault interrupt tripped signal to the processor.

21. The electric vehicle supply equipment of claim 20, wherein the processor is configured to perform the step of commanding by commanding the contactor to close after the ground fault interrupt tripped signal is received.

22. The electric vehicle supply equipment of claim 16, wherein the processor is configured to perform the step of detecting at the processor by verifying that the ground fault circuit sensed the simulated ground fault.

23. The electric vehicle supply equipment of claim 16, wherein the processor is configured to perform the step of commanding the contactor to close after detecting that the ground fault interrupt circuit sensed the simulated ground fault signal and prior to resetting the ground fault interrupt circuit.

24. The electric vehicle supply equipment of claim 16, wherein the processor is configured to perform the steps further comprising verifying that the contactor is not closed and that a ground fault interrupt tripped signal is not in the disabled state prior to providing a simulated ground fault signal to a ground fault circuit.

25. In an electric vehicle supply equipment for supplying electrical power from utility power to an electric vehicle, a processor configured to:
a) provide a simulated ground fault signal to a ground fault interrupt circuit;
b) detect that a ground fault interrupt circuit sensed the simulated ground fault signal;
c) command a utility power contactor to close while the ground fault interrupt circuit is disabling closing of the contactor; and
d) verify the contactor is not closed in response to the command to the utility power contactor to close.

26. The configured processor of claim 25, wherein the processor is configured to command by commanding the contactor to close in response to the processor detecting that the ground fault interrupt circuit sensed the simulated ground fault signal.

27. The configured processor of claim 26, wherein the processor is further configured to:
a) receive a request for charging via a pilot circuit; and
b) command the contactor to close in response to the request for charging prior to resetting the ground fault interrupt circuit.

28. The configured processor of claim 25, wherein the processor is further configured to:
a) reset the ground fault interrupt circuit while commanding the contactor to close; and
b) verify the contactor closes after the resetting of the ground fault interrupt circuit commanding the contactor to close.

29. The configured processor of claim 28, wherein the processor is configured to command by commanding the contactor to close after a ground fault interrupt tripped signal is received.

30. The configured processor of claim 25, wherein the processor is configured to detect by verifying that the ground fault circuit sensed the simulated ground fault.

31. The configured processor of claim 25, wherein the processor is configured to command the contactor to close after detecting that the ground fault interrupt circuit sensed the simulated ground fault signal and prior to resetting the ground fault interrupt circuit.

32. The configured processor of claim 25, wherein the processor is further configured to verify that the contactor is not closed and that a ground fault interrupt tripped signal is not in the disabled state prior to providing a simulated ground fault signal to a ground fault circuit.
